(19) United States
(12) Patent Application Publication
(10) Pub. No.: US 2026/0125792 A1
(43) Pub. Date: May 7, 2026

(54) SHOWERHEAD GAS INLET MIXER

(71) Applicant: LAM RESEARCH CORPORATION, Fremont, CA (US)

(72) Inventors: Gary B. LIND, Penn Valley, CA (US); Leonard KHO, San Francisco, CA (US); Atul Kumar GARG, Banda Belai (IN); Arun Kumar HOSUR SHIVALINGE GOWDA, Bangalore (IN); Karl Frederick LEESER, West Linn, OR (US)

(21) Appl. No.: 19/117,165

(22) PCT Filed: Sep. 27, 2023
(86) PCT No.: PCT/US2023/033788

§ 371 Date: Mar. 31, 2025

Related U.S. Application Data
(60) Provisional application No. 63/413,841, filed on Oct. 6, 2022.

(51) Int. Cl. C23C 16/455; C23C 16/509

(52) U.S. Cl. CPC C23C 16/45512; C23C 16/45565; C23C 16/5096

(57) ABSTRACT

A showerhead for a substrate processing chamber includes a head portion configured to receive a gas mixture and a stem portion coupled to the head portion. A first plenum is defined within the head portion and the gas mixture flows into the plenum and from the plenum into the substrate processing chamber via holes arranged in a lower surface of the head portion. The stem portion is configured to supply the gas mixture to the head portion through a central bore. A mixing chamber is arranged on the stem portion. The mixing chamber is configured to receive a first gas supplied from a first mixer inlet and a second gas supplied from a second mixer inlet, mix the first gas and the second gas into the gas mixture, and direct the gas mixture into an upper end of the central bore to be supplied downward into the head portion.

### CROSS-REFERENCE TO RELATED APPLICATIONS

This application claims the benefit of U.S. Provisional Application No. 63/413,841, filed on Oct. 6, 2022. The entire disclosure of the application referenced above is incorporated herein by reference.

### FIELD

The present disclosure relates to a showerhead inlet design for substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing tool typically comprises a plurality of stations in which to perform deposition, etching, and other treatments on substrates such as semiconductor wafers. Examples of processes that may be performed on a substrate comprise a chemical vapor deposition (CVD) process, a chemically enhanced plasma vapor deposition (CEPVD) process, a plasma enhanced chemical vapor deposition (PECVD) process, a sputtering physical vapor deposition (PVD) process, atomic layer deposition (ALD), and plasma enhanced ALD (PEALD). Additional examples of processes that may be performed on a substrate comprise etching (e.g., chemical etching, plasma etching, reactive ion etching, etc.) and cleaning processes.

During processing, the substrate is disposed in the processing chamber on a substrate support such as an electrostatic chuck (ESC) or a pedestal. Process gases are introduced and, in some examples, plasma is struck in the processing chamber. The process gases are introduced using a gas distribution device, such as a showerhead.

### SUMMARY

A showerhead for a substrate processing chamber includes a head portion configured to receive at least a first gas mixture and a stem portion coupled to the head portion. At least a first plenum is defined within the head portion and the first gas mixture flows into the first plenum and from the first plenum into a deposition zone of the substrate processing chamber via holes arranged in a lower surface of the head portion. The stem portion is configured to supply the first gas mixture to the head portion through a central bore defined within the stem portion. A mixing chamber is arranged on the stem portion. The mixing chamber is configured to receive a first gas supplied from a first mixer inlet and a second gas supplied from a second mixer inlet, mix the first gas and the second gas into the first gas mixture, and direct the first gas mixture into an upper end of the central bore to be supplied downward into the head portion

In other features, the mixing chamber is arranged at an upper end of the stem portion around the central bore and the mixing chamber is configured to direct the first gas mixture upward within the mixing chamber and into the upper end of the central bored. The showerhead further includes a plurality of mixer outlets extending upward from an upper end of the mixing chamber toward the upper end of the central bore. The showerhead further includes a valve assembly arranged above the mixing chamber. The valve assembly is configured to selectively allow fluid communication between the mixer outlets and the upper end of the central bore.

In other features, the mixing chamber is configured to receive a third gas supplied from a third mixer inlet and mix the third gas with the first gas and the second gas into the first gas mixture. The first mixer inlet, the second mixer inlet, and the third mixer inlet are arranged at an angle tangential to an outer surface of the mixing chamber. The first mixer inlet, the second mixer inlet, and the third mixer inlet are arranged such that the first gas, the second gas, and the third gas are supplied into the mixing chamber at an angle tangential to an inner surface of the mixing chamber.

In other features, a bottom surface of the mixing chamber is configured to direct the first gas mixture upward within the mixing chamber. The bottom surface is curved. The showerhead further includes a first inlet arranged to supply a second gas mixture to the stem portion. The first inlet is coupled to a first mixing tube configured to receive at least the first gas and the second gas, mix the first gas and the second gas into the second gas mixture, and supply the second gas mixture to a middle zone of the head portion via the first inlet and the stem portion.

In other features, the showerhead further includes a second inlet arranged to supply a third gas mixture to the stem portion. The second inlet is coupled to a second mixing tube configured to receive at least the first gas and the second gas, mix the first gas and the second gas into the third gas mixture, and supply the third gas mixture to an edge zone of the head portion via the second inlet and the stem portion. Each of the first mixing tube and the second mixing tube includes at least one of a mixing structure arranged within in an interior volume, a plurality of projecting features extending radially inward from an interior surface into the interior volume, and one or more helical grooves defined in the interior surface.

In other features, the showerhead includes a faceplate having a center zone, a middle zone located radially outside of the center zone, and an edge zone located radially outside of the middle zone. The faceplate includes a first plurality of holes distributed throughout the center zone and the middle zone and a second plurality of holes distributed throughout the edge zone. The showerhead includes a middle plate and a backplate. The middle plate is disposed between the faceplate and the backplate. The faceplate is configured to receive the first gas mixture supplied to the first plenum and supply the first gas mixture to the deposition zone via the first plurality of holes.

In other features, the showerhead further includes a first inlet arranged to supply a second gas mixture to the stem portion and a second inlet arranged to supply a third gas mixture to the stem portion. The faceplate includes a middle zone located radially outside of the center zone. The faceplate is configured to receive the second gas mixture in the middle zone via the first inlet of the stem portion and a middle inlet of the head portion. The faceplate includes an edge zone located radially outside of the middle zone. The faceplate is configured to receive the third gas mixture in the edge zone via the second inlet of the stem portion and an edge inlet of the head portion.

A showerhead for a substrate processing chamber includes a head portion defining a center zone, a middle zone located radially outside of the center zone, and an edge zone located radially outside of the middle zone. The head portion is configured to receive a first gas mixture in the center zone, a second gas mixture in the middle zone, and a third gas mixture in the edge zone. The showerhead includes a stem portion coupled to the head portion. The stem portion is configured to supply the first gas mixture to the center zone of the head portion through a central bore defined within the stem portion, supply the second gas mixture to the middle zone of the head portion through a middle inlet, and supply the third gas mixture to the edge zone of the head portion through an edge inlet. A mixing chamber is arranged on the stem portion. The mixing chamber is configured to receive a first gas supplied from a first mixer inlet, a second gas supplied from a second mixer inlet, and a third gas supplied form a third mixer inlet, mix the first gas, the second gas, and the third gas into the first gas mixture, and direct the first gas mixture into an upper end of the central bore to be supplied downward into the center zone of the head portion.

In other features, the showerhead further includes a first inlet arranged to supply the second gas mixture to the stem portion, the first inlet coupled to a first mixing tube configured to receive the first gas, the second gas, and the third gas and mix the first gas, the second gas, and the third gas into the second gas mixture, and a second inlet arranged to supply the third gas mixture to the stem portion, the second inlet coupled to a second mixing tube configured to receive the first gas, the second gas, and the third gas and mix the first gas, the second gas, and the third gas into the third gas mixture.

In other features, the first mixer inlet, the second mixer inlet, and the third mixer inlet are arranged such that the first gas, the second gas, and the third gas are supplied into the mixing chamber at an angle approximately tangential to an inner surface of the mixing chamber. A system includes the showerhead and a substrate processing chamber configured to perform bulk deposition on a substrate. The system further includes a controller configured to control a gas delivery system to independently supply the first gas, the second gas, and the third gas to each of the mixing chamber, the first mixing tube, and the second mixing tube.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a substrate processing system comprising an example carrier ring according to the present disclosure;

FIG. 2 shows an example processing chamber, showerhead, and substrate support according to the present disclosure;

FIG. 3 shows an example showerhead including a mixer assembly according to the present disclosure;

FIG. 4A is a plan view of an example mixing chamber according to the present disclosure;

FIG. 4B is a side view of an example mixing chamber according to the present disclosure;

FIGS. 4C and 4D illustrate gas flow within the mixing chamber of FIGS. 4A and 4B;

FIGS. 5A and 5B are plan views of an example mixing tube according to the present disclosure; and

FIG. 5C is a side view of an example mixing tube according to the present disclosure.

In the drawings, reference numbers may be reused to identify similar and/or identical elements.

### DETAILED DESCRIPTION

A substrate processing tool comprises one or more process modules or chambers. For example, a multi-station module (e.g., a quad-station module (QSM)) comprises a plurality of stations in which to perform deposition, etching, and other treatments on substrates. Different processes may be performed in respective stations. Conversely, a single station module comprises only a single station.

In some examples, a nucleation process (e.g., an atomic layer deposition (ALD) nucleation step) is performed in a first station of a multi-station module while bulk fill/deposition steps are performed in other stations of the multi-station module. Optimal chamber dimensions and geometry and/or process parameters may differ for respective steps. For example, optimal chamber pressure and temperature for the nucleation step may be lower than optimal chamber pressure and temperature for bulk deposition steps. However, since the stations in a multi-station module share the same processing chamber, processing chamber conditions may not be optimal for either nucleation or bulk deposition steps.

A process module according to the present disclosure comprises components optimized for bulk deposition steps of an ALD process. For example, the process module is a single station module configured to perform bulk deposition steps separately from a nucleation step. The nucleation step may be performed in a different module or tool prior to being transferred to the process module. Accordingly, nucleation and bulk deposition steps can be performed in respective optimal process conditions. Although described with respect to bulk deposition, the principles of the present disclosure may also be applied to other types of deposition.

The process module comprises a showerhead configured to perform bulk deposition. The showerhead includes a mixer assembly configured to direct gases within the showerhead into a mixing chamber prior to being supplied downward through the showerhead and into the processing chamber.

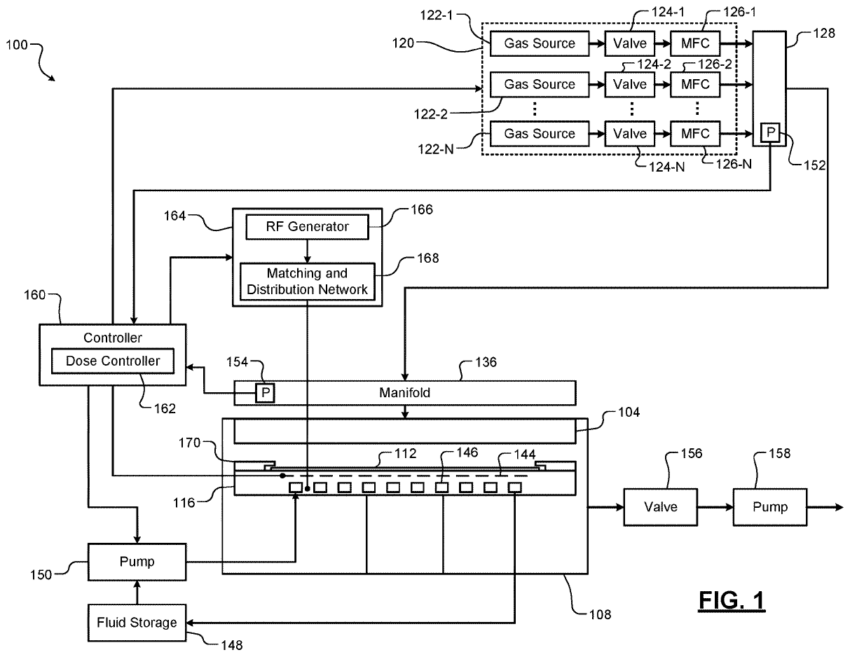

Referring now to FIG. 1, an example of a substrate processing system 100 comprising a showerhead 104 according to the present disclosure is shown. The showerhead 104 is arranged within an upper surface or portion of a processing chamber 108. A substrate 112 is arranged on a substrate support 116 (e.g., a pedestal configured for CVD and/or ALD deposition) during processing. For example, bulk deposition of an ALD process is performed on the substrate 112.

A gas delivery system 120 comprises gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126). The MFCs 126 control flow of gases from the gas sources 122 to a manifold 128 where the gases mix. An output of the manifold 128 is supplied to a manifold 136. An output of the manifold 136 is input the showerhead 104 (e.g., a multi-injector, multi-zone showerhead as described below in more detail). While the manifold 128 and 136 are shown, a single manifold can be used.

In some examples, a temperature of the substrate support 116 may be controlled using resistive heaters 144. The substrate support 116 may comprise coolant channels 146. Cooling fluid is supplied to the coolant channels 146 from a fluid storage 148 and a pump 150. Pressure sensors 152, 154 may be arranged in the manifold 128 or the manifold 136, respectively, to measure pressure. A valve 156 and a pump 158 may be used to evacuate reactants from the processing chamber 108 and/or to control pressure within the processing chamber 108.

A controller 160 comprises a dose controller 162 that controls dosing provided by the showerhead 104. The controller 160 also controls gas delivery from the gas delivery system 120. The controller 160 controls pressure in the processing chamber and/or evacuation of reactants using the valve 156 and the pump 158. The controller 160 controls the temperature of the substrate support 116 and the substrate 112 based upon temperature feedback (e.g., from sensors (not shown) in the substrate support and/or sensors (not shown) measuring coolant temperature).

Although described as being configured to perform deposition processes, the substrate processing system 100 may be configured to perform etching processes. In some examples, the substrate processing system 100 may be configured to perform etching on the substrate 112 within the same processing chamber 108 as deposition processes. Accordingly, the substrate processing system 100 may comprise an RF generating system 164 configured to generate and provide RF power (e.g., as a voltage source, current source, etc.) to one of a lower electrode (e.g., a baseplate of the substrate support 116, as shown) and an upper electrode (e.g., the showerhead 104). The other one of the lower electrode and the upper electrode may be DC grounded, AC grounded or floating.

For example only, the RF generating system 164 may comprise an RF generator 166 configured to generate the RF voltage that is fed by a matching and distribution network 168 to generate plasma within the processing chamber 108 to etch the substrate 112. In other examples, the plasma may be generated inductively or remotely. Although, as shown for example purposes, the RF generating system 164 corresponds to a capacitively coupled plasma (CCP) system, the principles of the present disclosure may also be implemented in other suitable systems, such as, for example only, transformer coupled plasma (TCP) systems, CCP cathode systems, remote microwave plasma generation and delivery systems, etc.

The substrate support 116 comprises a carrier ring 170. In some examples, an inner edge of the carrier ring 170 overlaps an outer edge of the substrate 112. In some examples, the substrate support 116 is lowered for transfer of the substrate 112 into the processing chamber 108. For example, the substrate 112 is transferred onto lift pins (not shown) that are exposed when the substrate support 116 is lowered. The substrate support 116 is then raised to engage the substrate 112 and the carrier ring 170.

FIG. 2 shows an example processing chamber 200 comprising a showerhead 204 according to the present disclosure. In an example, the processing chamber 200 corresponds to a station of a single station module. The processing chamber 200 is configured to perform a bulk deposition step on a substrate 208 subsequent to a nucleation step performed in a different processing chamber. For example, subsequent to a nucleation step, the substrate 208 is transferred to a substrate support (e.g., a pedestal) 212 arranged within the processing chamber 200.

In one example, the substrate 208 is transferred through a slot or other opening 214 in a sidewall of the processing chamber 200 when the pedestal 212 is in a lowered position. When the pedestal 212 is in the lowered position, lift pins 216 extend above an upper surface of the pedestal 212 and the substrate 208 is placed onto the lift pins 216 (e.g., using a transfer robot). The pedestal 212 is then raised to lift and support the substate 208 in a raised position as shown in FIG. 2.

Each of the processing chamber 200, the showerhead 204, and the pedestal 212 is configured to minimize azimuthal non-symmetries in a deposition zone 218 defined between the showerhead 204 and the pedestal 212. For example, the deposition zone 218 is a symmetrically annular volume defined between a lower, substrate-facing faceplate 220 of the showerhead 204, an annular inner surface 222 of the processing chamber 200, and the pedestal 212. Further, a gap between the faceplate 220 and the pedestal 212 is minimized to maintain uniformity of process gas flow and distribution within the deposition zone 218.

The showerhead 204 is comprised of a base or head portion 226 and a stem portion 228. The stem portion 228 extends through an upper wall (e.g., a lid 230) of the processing chamber 200 to connect to the head portion 226. For example, the head portion 226 comprises the faceplate 220, a backplate 232, and a middle plate 234 disposed between the faceplate 220 and the backplate 232. In this example, the faceplate 220 functions as an upper surface of the processing chamber 200.

The faceplate 220, the backplate 232, and the middle plate 234 define at least three flow paths and respective plenums 238 within the head portion 226 to provide radial tunability and process configurability. For example, one or more plenums 238-1 are defined in an upper surface of the faceplate 220, a plenum 238-2 is defined in an upper surface of the middle plate 234, a plenum 238-3 is defined in an upper surface of the backplate 232, and a plenum 238-4 is defined in the faceplate 220 radially outside of the plenum 238-1. The plenums 238-1, 238-2, 238-3, and 238-4 are referred to collectively as plenums 238.

As shown, a first flow path (shown as solid lines/arrows) 240 supplies gases through the stem 228 and into a corresponding plenum defined in a center zone 242 of the faceplate 220. A second flow path (shown as dotted lines/arrows) 244 supplies gases through the stem 228 and into a corresponding plenum defined in a radial or middle zone 246 of the faceplate 220. A third flow path (shown as dashed lines/arrows) 248 supplies gases through the stem 228 and into a corresponding plenum defined in an outer or edge zone 250 of the faceplate 220. For example only, the first flow path 240 is routed through the stem 228 to supply gases to the center zone 242 via a center inlet 252-1, the second flow path 244 is routed through the backplate 232 and the middle plate 234 to supply gases to the middle zone 246 through a middle inlet 252-2, and the third flow path 248 is routed through the backplate 232 and the middle plate 234 to supply gases to the edge zone 250 through an edge inlet 252-3.

The faceplate 220 includes a plurality of holes 254 extending from the plenums 238 to the deposition zone 218 within the processing chamber 200. For example, gases in the first flow path 240 flow through holes 254 in the center zone 242, gases in the second flow path 244 flow through holes 254 in the middle zone 246, and gases in the third flow path 248 flow through holes 254 in the edge zone 250.

Gases supplied to the center zone 242, the middle zone 246, and the edge zone 250 can be independently controlled to either add or delete specific reactants (i.e., gases) supplied to corresponding regions of the substrate 208. For example only, a gas mixture supplied to the deposition zone 218 to perform bulk deposition may include various reactive and non-reactive gases, such as argon (Ar), molecular hydrogen (H₂), tungsten hexafluoride (WF₆), molecular nitrogen (N₂), etc. Other gases and gas mixtures may be supplied in other examples, such as diborane (C₂H₆), silane (SiH₄), etc. Amounts of each of the gases supplied to the respective zones 242, 246, 250 can be controlled (e.g., using separately controllable components of a gas control system, such as the gas control system 120) to tune deposition rates and film properties in the different regions of the substrate 208. In other words, amounts of each gas supplied to each of the zones can be independently controlled.

As shown in FIG. 2, gases provided to the edge zone 250 via the third flow path 248 are provided only to outermost holes 260 in the faceplate 220. In other words, the third flow path 248 does not supply gases to the center zone 242 and the middle zone 246. For example, the holes 260 are in fluid communication with the plenum 238-3 and the plenum 238-4 defined in the edge zone 250 of the faceplate 220 but are not in fluid communication with the plenum 238-1 defined in the center zone 242 and the middle zone 246. As an example, the plenum 238-4 in the edge zone 250 is separated from the plenum 238-1 in the center zone 242 and the middle zone 246.

Conversely, the plenum 238-1 may correspond to a single plenum defined in both the center zone 242 and the middle zone 246. Accordingly, gases supplied via both the first flow path 240 and the second flow path 244 are supplied to the same plenum 238-1. The gases supplied via the first flow path 240 and the second flow path 244 are blended within the plenum 238-1 and flow through the holes 254.

The showerhead 204 according to the present disclosure includes a mixer assembly 264. The mixer assembly 264 is configured to direct gases within the showerhead 204 into a mixing chamber 268 defined within the mixer assembly 264 prior to being supplied downward through the stem portion 228 and into the plenums 238 as described below in more detail.

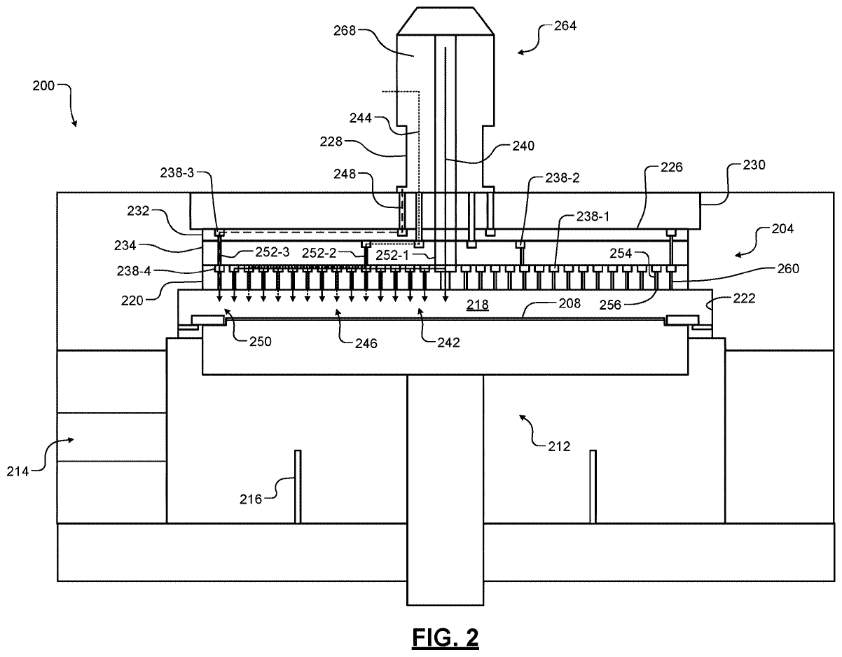

Referring now to FIG. 3, an example showerhead 300 including a mixer assembly 304 according to the present disclosure is shown. As an example, the showerhead 300 is shown as a simplified version of the showerhead of 204 of FIG. 2. The mixer assembly 304 is configured to direct gases within the showerhead 300 into a mixing chamber 308 defined within the mixer assembly 304 prior to being supplied downward through a stem portion 312 of the showerhead 300 and into plenums (not shown in FIG. 3) defined within a head portion 316 of the showerhead 300. In some examples (as shown), the mixing chamber 308 is integrated with the stem portion 312. In other examples, the mixing chamber 308 is a separate component coupled to an upper end of the stem portion 312.

Two or more mixer inlets (e.g., mixer inlets 320-1, 320-2, and 320-3, referred to collectively as mixer inlets 320) separately supply different gases to the mixing chamber 308. For example, the mixer inlets 320 supply gases such as Ar, H₂, and WF₆ to be mixed and supplied to the head portion 316 via a center inlet 324 (e.g., at a lower end of a central channel or bore 328 through the stem portion 312). The mixer inlets 320 are arranged at angles tangential or approximately tangential to (e.g., within 10 degrees of) an outer diameter of the mixing chamber 308. In other words, the mixer inlets 320 are arranged to supply gases into the mixing chamber 308 at an angle tangential to an inner surface of the mixing chamber 308. Accordingly, gases injected into the mixing chamber 308 flow in upward, circular flow patterns (e.g., an upward spiral) toward an upper end of the mixing chamber 308. The respective flow patterns facilitate mixing of the gases within the mixing chamber 308.

The mixed gases flow upward from the mixing chamber 308 and into a valve assembly 332 via a plurality of mixer outlets 336. The valve assembly 332 is arranged above the stem portion 312 and selectively provides fluid communication between the outlets 336 and the central bore 328. For example, in a first state, the valve assembly 332 flows gases supplied from an inlet 340 into the central bore 328. In the first state, the valve assembly 332 prevents gas flow from the mixer outlets 336 to the central bore 328. As one example, the inlet 340 supplies remote plasma clean gases to the showerhead 300. In a second state, the valve assembly 332 flows mixed gases supplied from the mixer outlets 336 to the central bore 328 (e.g., during deposition processing as described above).

Conversely, gases supplied to the showerhead 300 to be provided to middle and edge zones as described above are supplied to the stem portion 312 via inlets 344 and 348, respectively. For example, a plurality of gases (e.g., Ar, H₂, and WF₆) are separately supplied to a middle zone manifold assembly 350 and an edge zone manifold assembly 352. The gases from the manifold assemblies 350, 352 are supplied to respective mixing tubes 354, 356. The mixing tubes 354, 356 are respectively arranged between the manifold assemblies 350, 352 and the inlets 344, 348. The mixing tubes 354, 356 are configured to mix the gases supplied to the manifold assemblies 350, 352 prior to being supplied to the middle and edge zones as described below in more detail. In some examples, the mixing tubes 354, 356 are removably coupled to the manifold assemblies 350, 352 and the inlets 344, 348 to facilitate removal for replacement, cleaning, etc.

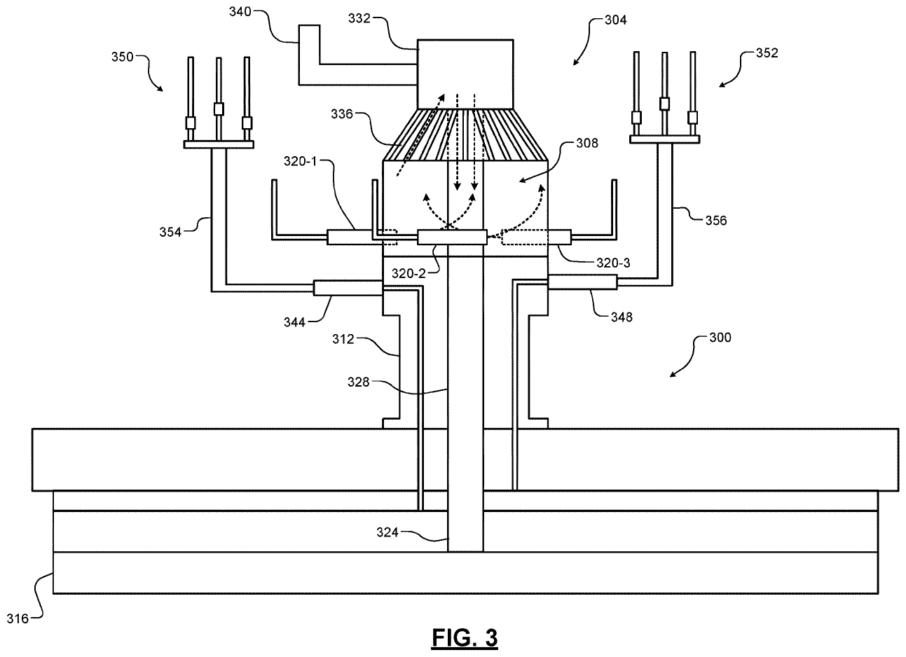

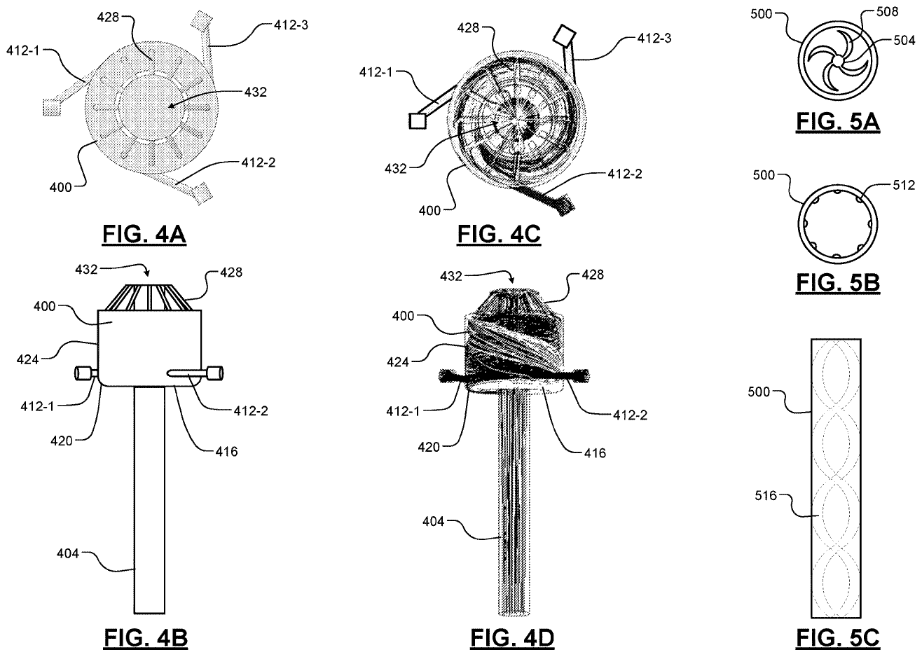

Referring now to FIGS. 4A, 4B, 4C, and 4D, operation of an example mixing chamber 400 is described in more detail. FIG. 4A is a plan (top down) view of the mixing chamber 400. FIG. 4B is a side view of the mixing chamber 400 and a central bore 404 defined within a stem portion of a showerhead (e.g., corresponding to the central bore 328 of the stem portion 312 of FIG. 3). FIGS. 4C and 4D illustrate gas flow within the mixing chamber 400 and the central bore 404 in the plan view and the side view, respectively.

Mixer inlets 412-1, 412-2, and 412-3 (referred to collectively as mixer inlets 412) supply respective gases to the mixing chamber 400 as described above in FIG. 3. As shown, each of the mixer inlets 412 is arranged at an angle tangential to the mixing chamber 400. In other words, the mixing chamber 400 is generally circular and the mixer inlets 412 are aligned with/parallel to a line approximately (e.g., +/−5 degrees) tangential to an outer diameter of the mixing chamber 400. In some examples, each of the mixer inlets 412 is arranged at a same angle relative to the mixing chamber 400. In other examples, the mixer inlets 412 are arranged at different angles. For example, one or more of the mixer inlets 412 may be arranged at an angle non-tangential to the outer diameter of the mixing chamber 400.

The mixer inlets 412 may be uniformly (as shown) or non-uniformly spaced around the mixing chamber 400. The mixer inlets 412 may be generally horizontal (i.e., perpendicular to a central axis of the mixing chamber 400 and the central bore 404). In some examples, one or more of the mixer inlets 412 may be angled in a vertical direction such that gases are supplied at an upward or downward angle into the mixing chamber 400.

Accordingly, angles and spacing of the mixer inlets 412 may be varied to achieve a desired flow pattern and mixing turbulence within the mixing chamber 400. For example, different gases supplied to the mixing chamber 400 may have different weights, densities, or other flow characteristics. The corresponding mixer inlets 412 for each of the gases can be arranged according to the different flow characteristics of the gases to optimize mixing within the mixing chamber 400.

The mixer inlets 412 are arranged near (e.g., within 15 mm of) a bottom surface 416 of the mixing chamber 400. For example, the mixer inlets 412 are arranged to supply gases to a lower half of the mixing chamber 400. In some examples, the bottom surface 416 is rounded or curved. For example, an interface 420 between sidewalls 424 and the bottom surface 416 is curved. In this manner, the bottom surface 416 may be configured to facilitate upward flow of the gases within the mixing chamber 400.

The arrangement of the mixer inlets 412 and the mixing chamber 400 is configured to generate an upward circular flow of mixed gases toward mixer outlets 428. The mixer outlets 428 supply the mixed gases to an upper opening 432 of the central bore 404, which in turn supplies the mixed gases to a base portion of the showerhead as described above in FIG. 3.

FIGS. 5A and 5B are plan (top down) views of an example mixing tube 500 according to the present disclosure. FIG. 5C is a side view of the example mixing tube 500. The mixing tube 500 corresponds to the mixing tubes 354, 356 arranged to supply gases to middle and edge zones as described above in FIG. 3. The mixing tube 500 is configured to mix gases prior to supplying the gases to the middle and edge zones.

For example, as shown in FIG. 5A, the mixing tube 500 may include a mixing structure 504. The mixing structure 504 is arranged within an interior volume of the mixing tube 500 and extends along a vertical axis of the mixing tube 500. The mixing structure 504 includes mixing features 508 such as curved spokes, blades, etc. In other examples, the mixing structure 504 may have a helical ribbon shape, a twisted ribbon shape, etc. The mixing structure 504 is configured to cause turbulence within the mixing tube 500 to facilitate mixing of gases within the mixing tube 500 prior to being supplied to the showerhead.

In another example shown in FIG. 5B, an interior surface of the mixing tube 500 includes a plurality of projecting features 512 extending radially inward into the interior volume of the mixing tube 500. While as shown the features 512 are semi-circular, other shapes may be used. The features 512 may correspond to individual bumps distributed across the interior surface, vertical ridges that extend vertically along the interior surface or spiral downward along the interior surface, etc. The features 512 increase turbulence within the interior volume of the mixing tube 500 to facilitate mixing of gases within prior to being supplied to the showerhead.

In still another example shown in FIG. 5C, one or more helical grooves 516 are defined in the interior surface of the mixing tube 500. The helical grooves 516, like the structure 504 and the features 512, increase turbulence within the interior volume of the mixing tube 500 to facilitate mixing of gases within prior to being supplied to the showerhead. In other examples, other components of the showerhead (e.g., channels defined within the stem portion 312 between the inlets 344, 348 and the head portion 316) may include features configured to facilitate mixing of gases prior to being supplied to respective plenums.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A showerhead for a substrate processing chamber, the showerhead comprising:
a head portion configured to receive at least a first gas mixture, wherein at least a first plenum is defined within the head portion, and wherein the first gas mixture flows into the first plenum and from the first plenum into a deposition zone of the substrate processing chamber via holes arranged in a lower surface of the head portion;
a stem portion coupled to the head portion, the stem portion configured to supply the first gas mixture to the head portion through a central bore defined within the stem portion; and
a mixing chamber arranged on the stem portion, the mixing chamber configured to (i) receive a first gas supplied from a first mixer inlet and a second gas supplied from a second mixer inlet, (ii) mix the first gas and the second gas into the first gas mixture, and (iii) direct the first gas mixture into an upper end of the central bore to be supplied downward into the head portion.

2. The showerhead of claim 1, wherein the mixing chamber is arranged at an upper end of the stem portion around the central bore, and wherein the mixing chamber is configured to direct the first gas mixture upward within the mixing chamber and into the upper end of the central bored.

3. The showerhead of claim 2, further comprising a plurality of mixer outlets extending upward from an upper end of the mixing chamber toward the upper end of the central bore.

4. The showerhead of claim 3, further comprising a valve assembly arranged above the mixing chamber, wherein the valve assembly is configured to selectively allow fluid communication between the mixer outlets and the upper end of the central bore.

5. The showerhead of claim 1, wherein the mixing chamber is configured to receive a third gas supplied from a third mixer inlet and mix the third gas with the first gas and the second gas into the first gas mixture.

6. The showerhead of claim 5, wherein the first mixer inlet, the second mixer inlet, and the third mixer inlet are arranged at an angle tangential to an outer surface of the mixing chamber.

7. The showerhead of claim 5, wherein the first mixer inlet, the second mixer inlet, and the third mixer inlet are arranged such that the first gas, the second gas, and the third gas are supplied into the mixing chamber at an angle tangential to an inner surface of the mixing chamber.

8. The showerhead of claim 1, wherein a bottom surface of the mixing chamber is configured to direct the first gas mixture upward within the mixing chamber.

9. The showerhead of claim 8, wherein the bottom surface is curved.

10. The showerhead of claim 1, further comprising a first inlet arranged to supply a second gas mixture to the stem portion, the first inlet coupled to a first mixing tube configured to (i) receive at least the first gas and the second gas, (ii) mix the first gas and the second gas into the second gas mixture, and (iii) supply the second gas mixture to a middle zone of the head portion via the first inlet and the stem portion.

11. The showerhead of claim 10, further comprising a second inlet arranged to supply a third gas mixture to the stem portion, the second inlet coupled to a second mixing tube configured to (i) receive at least the first gas and the second gas, (ii) mix the first gas and the second gas into the third gas mixture, and (iii) supply the third gas mixture to an edge zone of the head portion via the second inlet and the stem portion.

12. The showerhead of claim 11, wherein each of the first mixing tube and the second mixing tube includes at least one of (i) a mixing structure arranged within in an interior volume, (ii) a plurality of projecting features extending radially inward from an interior surface into the interior volume, and (iii) one or more helical grooves defined in the interior surface.

13. The showerhead of claim 1, the showerhead comprising:
a faceplate having a center zone, a middle zone located radially outside of the center zone, and an edge zone located radially outside of the middle zone, wherein the faceplate includes a first plurality of holes distributed throughout the center zone and the middle zone and a second plurality of holes distributed throughout the edge zone;
a middle plate; and
a backplate, wherein the middle plate is disposed between the faceplate and the backplate, and wherein
the faceplate is configured to receive the first gas mixture supplied to the first plenum and supply the first gas mixture to the deposition zone via the first plurality of holes.

14. The showerhead of claim 13, further comprising a first inlet arranged to supply a second gas mixture to the stem portion and a second inlet arranged to supply a third gas mixture to the stem portion.

15. The showerhead of claim 14, wherein:
the faceplate comprises a middle zone located radially outside of the center zone;
the faceplate is configured to receive the second gas mixture in the middle zone via the first inlet of the stem portion and a middle inlet of the head portion;
the faceplate comprises an edge zone located radially outside of the middle zone; and
the faceplate is configured to receive the third gas mixture in the edge zone via the second inlet of the stem portion and an edge inlet of the head portion.

16. A showerhead for a substrate processing chamber, the showerhead comprising:
a head portion defining a center zone, a middle zone located radially outside of the center zone, and an edge zone located radially outside of the middle zone, the head portion configured to receive a first gas mixture in the center zone, a second gas mixture in the middle zone, and a third gas mixture in the edge zone;
a stem portion coupled to the head portion, the stem portion configured to supply the first gas mixture to the center zone of the head portion through a central bore defined within the stem portion, supply the second gas mixture to the middle zone of the head portion through a middle inlet, and supply the third gas mixture to the edge zone of the head portion through an edge inlet; and
a mixing chamber arranged on the stem portion, the mixing chamber configured to (i) receive a first gas supplied from a first mixer inlet, a second gas supplied from a second mixer inlet, and a third gas supplied form a third mixer inlet, (ii) mix the first gas, the second gas, and the third gas into the first gas mixture, and (iii) direct the first gas mixture into an upper end of the central bore to be supplied downward into the center zone of the head portion.

17. The showerhead of claim 16, further comprising:
a first inlet arranged to supply the second gas mixture to the stem portion, the first inlet coupled to a first mixing tube configured to (i) receive the first gas, the second gas, and the third gas and (ii) mix the first gas, the second gas, and the third gas into the second gas mixture; and
a second inlet arranged to supply the third gas mixture to the stem portion, the second inlet coupled to a second mixing tube configured to (i) receive the first gas, the second gas, and the third gas and (ii) mix the first gas, the second gas, and the third gas into the third gas mixture.

18. The showerhead of claim 17, wherein the first mixer inlet, the second mixer inlet, and the third mixer inlet are arranged such that the first gas, the second gas, and the third gas are supplied into the mixing chamber at an angle approximately tangential to an inner surface of the mixing chamber.

19. A system, comprising:
a substrate processing chamber configured to perform bulk deposition on a substrate; and
the showerhead of claim 18.

20. The system of claim 19, further comprising a controller configured to control a gas delivery system to independently supply the first gas, the second gas, and the third gas to each of the mixing chamber, the first mixing tube, and the second mixing tube.
